(19) United States
(12) Patent Application Publication
(10) Pub. No.: US 2026/0005077 A1
(43) Pub. Date: Jan. 1, 2026

(54) PACKAGE SUBSTRATES WITH CORES HAVING SOLID GLASS AND GLASS FIBER PREPREG

(71) Applicant: Intel Corporation, Santa Clara, CA (US)

(72) Inventors: Brandon Christian Marin, Gilbert, AZ (US); Jeremy D. Ecton, Gilbert, AZ (US); Gang Duan, Chandler, AZ (US); Srinivas Venkata Ramanuja Pietambaram, Chandler, AZ (US)

(73) Assignee: Intel Corporation, Santa Clara, CA (US)

(21) Appl. No.: 18/756,204

(22) Filed: Jun. 27, 2024

(51) Int. Cl. H01L 23/08; H01L 23/522; H01L 23/528

(52) U.S. Cl. CPC H01L 23/08; H01L 23/5226; H01L 23/5283

(57) ABSTRACT

In one embodiment, an apparatus (e.g., a package substrate) includes a core with a layer comprising glass fibers in an epoxy material, a solid glass layer above or on the layer comprising glass fibers in the epoxy material, and a dielectric adjacent the solid glass layer.

### BACKGROUND

Continued growth in computing and mobile devices will continue to increase the demand for greater bandwidth density within and reliability of semiconductor packages. Some integrated circuit packages may implement glass cores, which can provide advantages over traditional packages with organic material cores (e.g., glass cores are thicker and can better resist warpage through the manufacturing process).

### BRIEF DESCRIPTION OF THE DRAWINGS

FIG. 1 illustrates an example package substrate with a core in accordance with embodiments herein.

FIG. 2 illustrates an example multi-die integrated circuit package with a core in accordance with embodiments herein.

FIG. 3 illustrates an example package substrate core with a glass layer on a layer comprising glass fibers in accordance with embodiments herein.

FIGS. 4A-4E illustrate an example process of fabricating a package substrate with a core in accordance with embodiments herein.

FIG. 5 illustrates an example package substrate core with a glass layer between layers comprising a glass fiber weave in accordance with embodiments herein.

FIGS. 6A-6B illustrate example systems that may incorporate the embodiments described herein.

FIG. 7 is a top view of a wafer and dies that may be included in embodiments disclosed herein.

FIG. 8 is a cross-sectional side view of an integrated circuit device that may be included in embodiments disclosed herein.

FIG. 9 is a block diagram of an example electrical device that may include any of the embodiments disclosed herein.

### DETAILED DESCRIPTION

Integrated circuit apparatuses continue to shrink in size, and with this shrinkage, improving device performance has been focused in two directions (1) to achieve chip stacking using thinned chips, and (2) increasing input/output (I/O) density in the substrate for multichip integration. Manufacturing these ever-increasing apparatuses has been made possible with a rigid carrier wafer, such as a glass-based core wafer, in a temporary bonding and debonding technology. However, one of the challenges associated with the temporary bonding and debonding technology is the warpage or shrinkage control after removal of the rigid carrier. Once the rigid glass carrier is de-bonded after bump formation, the substrate might be expected to warp due to inbuilt residual stress and CTE (coefficient of thermal efficiency) mismatch between various components, e.g., between Silicon (2.6 ppm/° C.), ABF (˜39 ppm/° C.) and Copper (17 ppm/° C.). This can impact the back-end process for bump formation and the assembly process.

One way to tackle the above problem is to use glass in the substrate core, as glass is stiffer than organic core materials (e.g., glass may have a modulus of elasticity of ˜ 60-90 GPa as compared with a modulus of elasticity ˜25-30 GPa for organic core materials). The permanent glass core can restrict warpage and may thereby maintain TTV requirements for smaller pitch scaling. However, cores comprised entirely of glass may be difficult to incorporate into manufacturing processes for package substrates or packages incorporating such substrates.

Embodiments herein may incorporate a glass layer (e.g., a solid amorphous glass layer) within a substrate core, wherein the glass layer is on a carrier layer comprising a glass fiber weave within epoxy (sometimes referred to herein or otherwise as a “glass cloth prepreg” layer or “glass fiber prepreg” layer) and encompassed within an organic mold. By encompassing the glass layer within these organic materials, the core can provide the benefits of a glass core, e.g., resisting warpage, while also being able to be incorporated into existing manufacturing methods for package substrates.

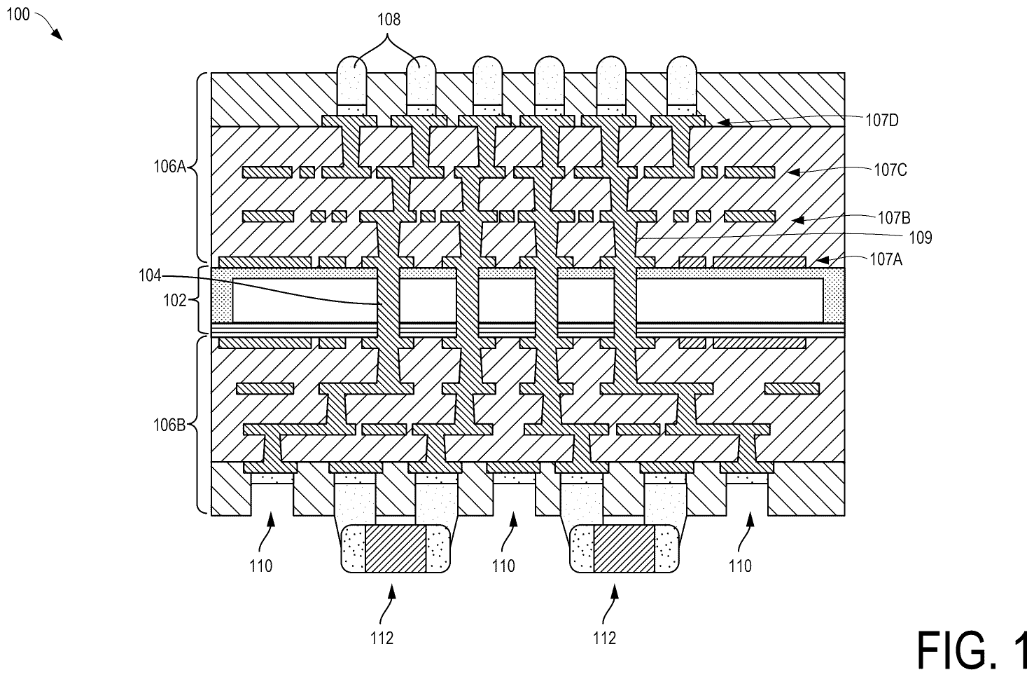

FIG. 1 illustrates an example package substrate 100 with a core in accordance with embodiments herein. In particular, the example package substrate 100 includes a core layer 102 with buildup layers 106 formed on either side of the core layer 102, i.e., with buildup layers 106A on the top side of the core layer 102 and buildup layers 106B on the bottom side of the core layer 102. The buildup layers 106 include metal traces in metallization layers (e.g., 107A-D) and pillars (e.g., 109) between the metallization layers to electrically couple the solder bumps 108 at the top of the package substrate 100 with the pads 110 at the bottom of the substrate. In certain instances, for example, an integrated circuit die may be coupled to a top side of the package substrate 100 and connect to the solder bumps 108, and the package substrate 100 may be coupled to a circuit board (e.g., a motherboard, main board, etc.) via the pads 110 at the bottom of the package substrate 100. The package substrate 100 also includes land side capacitors 112 coupled on a bottom side of the package substrate 100.

In addition, the package substrate 100 includes a circuit component 116 that is embedded within the core layer 102, i.e., within a cavity 103 in the core layer 102. The circuit component 116 may be a passive circuit component, such as a capacitor or inductor, in certain embodiments, and may be placed within a cavity (e.g., as shown) or hole in the core layer 102. In some embodiments, the component 116 may be encapsulated with a mold material inside the cavity/hole in the core layer 102. Although shown in FIG. 1 as being horizontally oriented, the component 116 (or multiple components) may be vertically oriented in the core layer 102 in embodiments herein, e.g., as described further below.

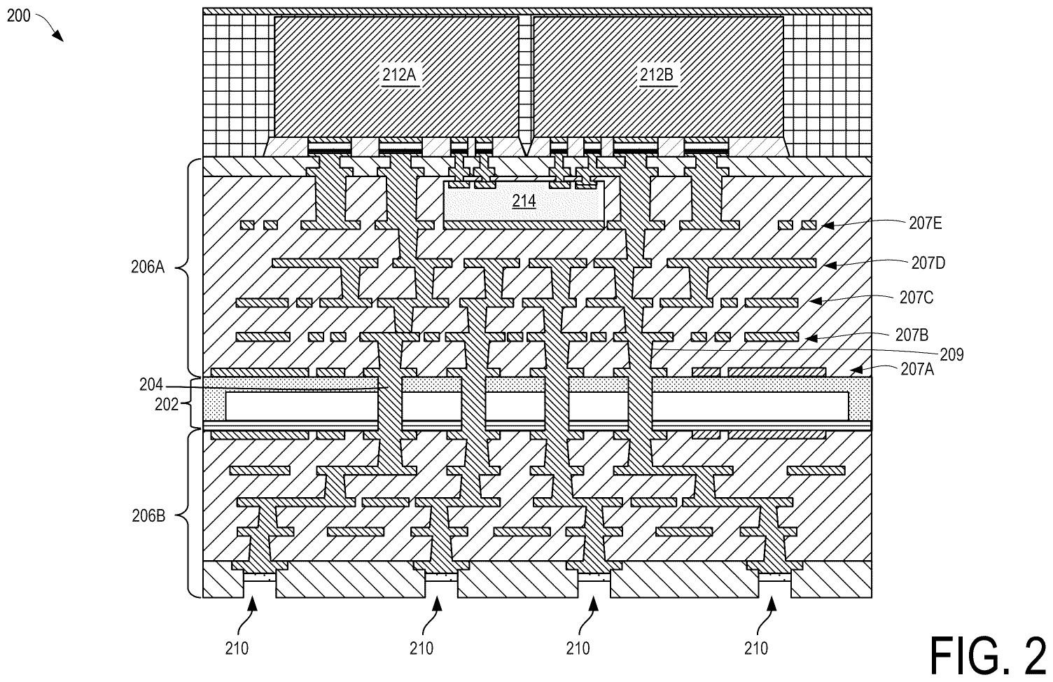

FIG. 2 illustrates an example multi-die integrated circuit package 200 with a core in accordance with embodiments herein. The package 200 includes a core layer 202 and vias 204 through the core layer 202. Buildup layers 206 are formed on the top and bottom sides of the core layer 202, with buildup layers 206A on the top side of the core layer 202 and the buildup layers 206B on bottom side of the core layer 202. The buildup layers 206 include metal traces in metallization layers (e.g., 207A-E) and pillars (e.g., 209) between the metallization layers as shown to electrically couple components on the top of the package 200 with the pads 210 at the bottom of the package. For example, the layers 206 may provide connections between the integrated circuit (IC) dies 212 coupled to the top side of the package to a circuit board (e.g., a motherboard, main board, etc.) via the pads 210 at the bottom of the package. The package 200 also includes a bridge circuitry component 214 located in the buildup layers 206A that electrically couples the first IC die 212A with the second IC die 212B. The bridge circuitry component 214 may include passive and/or active components to interconnect the IC dies 212. The bridge circuitry component 214 may be an Intel® embedded multi-die interconnect bridge (EMIB) in certain embodiments.

In addition, the package 200 includes a circuit component 216 that is embedded within the core layer 202, i.e., within a cavity 203 in the core layer 202. Like the component 116 of FIG. 1, the circuit component 216 may be a passive circuit component, such as a capacitor or inductor, in certain embodiments, and may be placed within a cavity (e.g., as shown) or hole in the core layer 202. In some embodiments, the component 216 may be encapsulated with a mold material inside the cavity/hole in the core layer 202. Although shown in FIG. 2 as being horizontally oriented, the component 216 (or multiple components) may be vertically oriented in the core layer 202 in embodiments herein, e.g., as described further below.

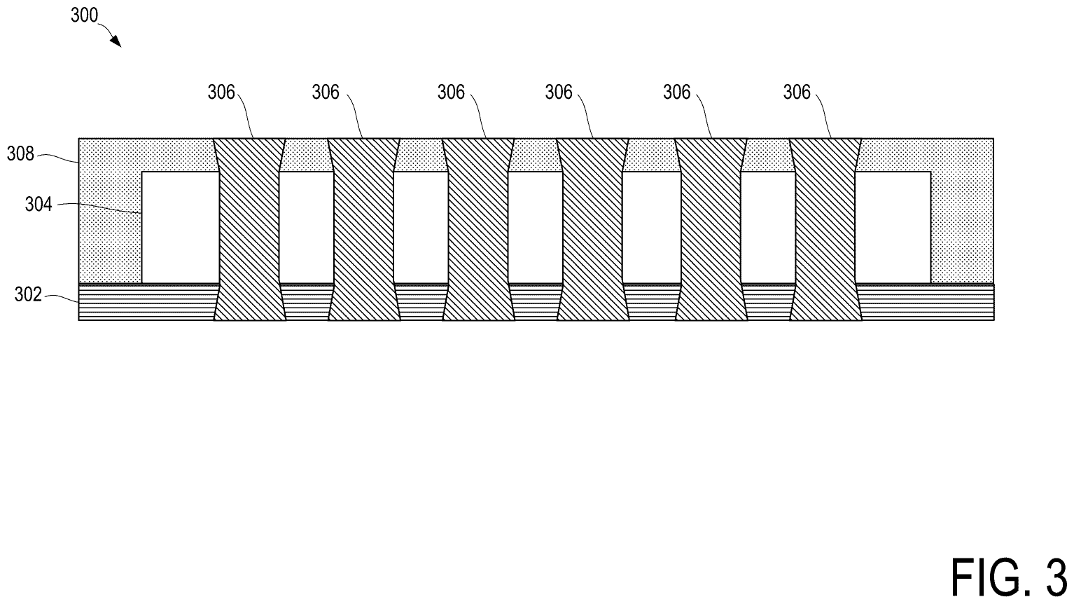

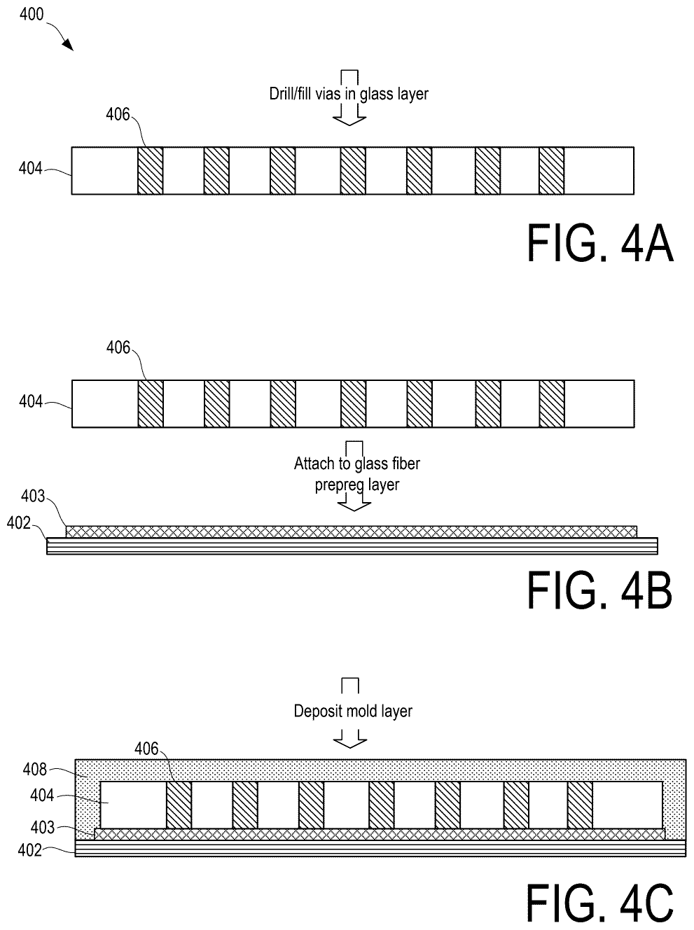

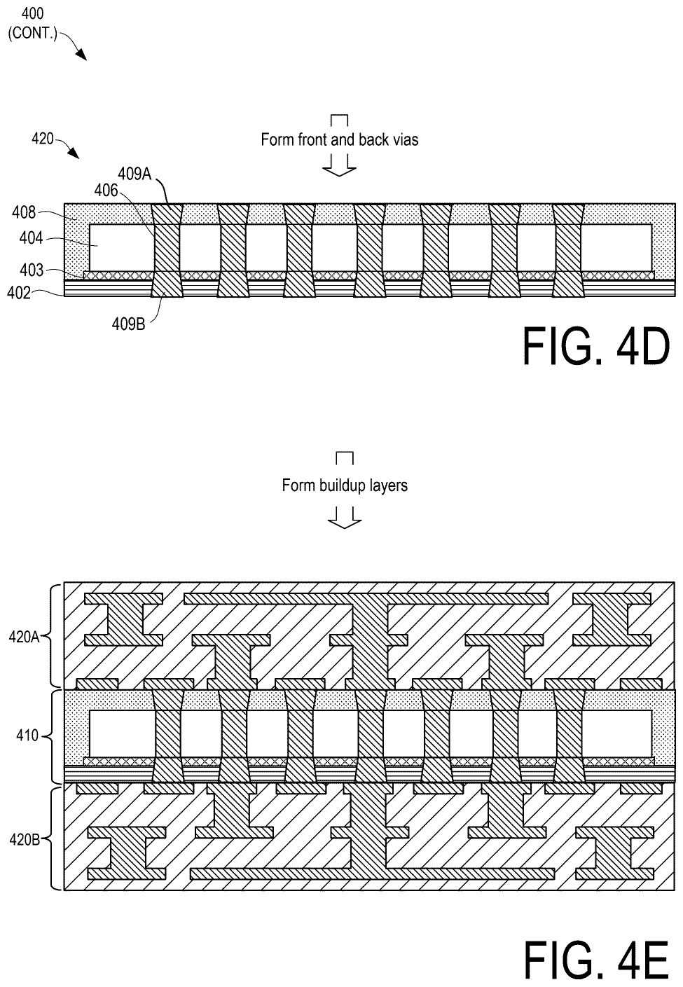

FIG. 3 illustrates an example package substrate core 300 with a glass layer 304 on a layer 302 comprising glass fibers in accordance with embodiments herein. A core such as the core 300 may be incorporated into a package substrate, e.g., similar to the core layer 102 or core layer 202 of FIGS. 1, 2, respectively. The core 300 includes a solid glass layer 304 on the layer 302 with a mold material 308 encompassing the glass layer 304. In some embodiments, the solid glass layer 304 may be placed directly on the layer 302. In some embodiments, there may be one or more intervening layers of material between the layer 302 and the solid glass layer 304. For example, the glass layer 304 may be bonded to the layer 302, e.g., using an adhesive film as shown in FIGS. 4A-4E and described below.

The layer 302 may include a glass cloth prepreg (GCP) material with a glass fiber weave in an epoxy material, which may be referred to, in some cases, as an e-glass prepreg. The layer 302 may include any suitable epoxy material (e.g., an organic epoxy material) with one or more glass cloth weaves therein. The glass cloth weave(s) inside the layer 302 may each be formed by weaving fibers of glass together to form fabric-like sheets, and the layer 302 may include one or more sheets. The glass fibers may have diameters of between 5-200 um, in certain embodiments. In some embodiments, sheets of glass cloth weave may be in accordance with IPC standards, e.g., IPC-4412A for finished fabric woven from “E” glass for printed boards, or may be in accordance with standards for other types of boards, such “S” glass-based or “LD” glass-based printed boards. The sheet(s) of glass cloth weave may be arranged horizontally within the layer 302, as shown in FIG. 3. That is, in certain embodiments, each sheet of glass weave may be laid generally in the same planar orientation as the glass layer 304. In certain embodiments, the layer 302 may be between 10-100 um thick (the vertical direction as shown in FIG. 3), e.g., approximately 25 um thick.

The glass layer 304 may include solid amorphous glass that comprises Silicon (e.g., at least 23% by weight) and Oxygen (e.g., at least 26% by weight), and may be formed with a rectangular prism volume. In some embodiments, the glass layer 304 may include one or more additive elements (e.g., as least 5% by weight) such as Aluminum, Boron, Magnesium, Calcium, Barium, Tin, Sodium, Potassium, Strontium, Phosphorus, Zirconium, Lithium, Titanium, and Zinc. For example, the glass layer 304 may be formed of one or more of the following example materials: aluminosilicate, borosilicate, alumino-borosilicate, silica, or fused silica. In some embodiments, the glass layer 304 may further include one or more additives, such as, for example, Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass layer 304 may be made of a spin-on glass (SOG) material. In some embodiments, the glass layer 304 may have a thickness (in the vertical direction of FIG. 3) between 50 um-250 mm.

The core 300 further mold material 308 is adjacent to, and encompasses, the glass layer 304 as shown. In some embodiments, the mold material 308 may be an organic epoxy material with silica fillers that are spherical or substantially spherical in shape. In addition, the core 300 includes metal vias 306 extending through the core 300 and electrically coupling the top layer of the core 300 to the bottom layer of the core 300, e.g., coupling metallization layers above and below the core 300 such as is shown in the examples of FIGS. 1-2.

FIGS. 4A-4E illustrate an example process 400 of fabricating a package substrate with a core in accordance with embodiments herein. The example process shown may include additional, fewer, or different operations than those shown or described below. In some embodiments, one or more of the operations shown include multiple operations, sub-operations, etc. The illustrations of FIGS. 4A-4E may accordingly represent different stages in the manufacturing process of a device, e.g., an integrated circuit package substrate.

As shown in FIG. 4A, through glass vias (TGVs) 406 are formed in a solid glass layer 404. The solid glass layer 404 may be formed with the same or similar materials as described above with respect to the glass layer 304. The TGVs 406 may be formed by forming holes through the glass layer 404, e.g., via laser drilling, and then filling the holes with a conductive material, e.g., metal, through suitable deposition techniques, e.g., plating. Next, as shown in FIG. 4B, the glass layer 404 with TGVs 406 is coupled to a carrier layer 402, which is the same as or similar to the layer 302 described above (that is, with glass fibers within an epoxy material). The coupling may be achieved with an adhesive film 403, which may be between approximately 1-5 um thick in certain embodiments. A mold material 408 may be formed around the glass layer 404 as shown in FIG. 4C. The mold material 408 may be the same as or similar to the mold material 308 described above. In some embodiments, a top portion of the mold material 408 can be removed, e.g., via grinding or mechanical polishing, to expose the glass layer 404, and another layer similar to the layer 402 can be placed on top of the glass layer 404 to form a core similar to the core 500 described below. Next, top vias 409A and bottom vias 409B are formed above and below at least certain of the TGVs 406 as shown in FIG. 4D to form a core assembly 410. Finally, buildup layers 420A, 402B can be formed above and below the core assembly 410. The buildup layers include one or more metallization layers within dielectric, similar to the buildup layers 106, 206 described above. The buildup layers can be formed through traditional techniques, in certain embodiments.

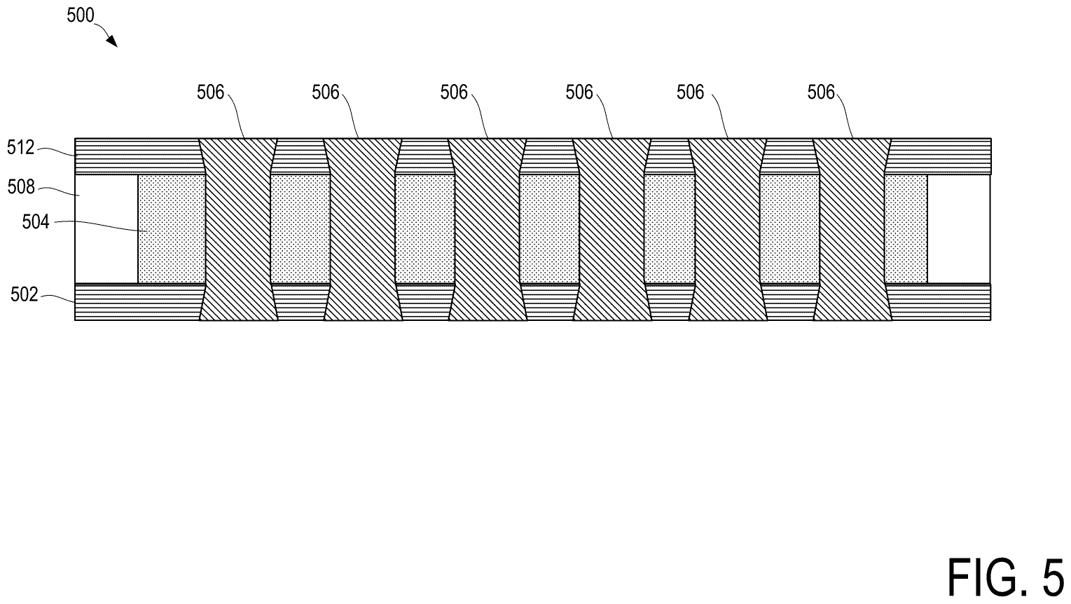

FIG. 5 illustrates an example package substrate core 500 with a glass layer 504 between layers 502, 512 comprising a glass fiber weave in accordance with embodiments herein. The example core 500 is similar to the core 300 of FIG. 3, except that the core 500 includes a bottom layer 502 similar to the layer 302 of the core 300 as well as a top layer 512 of the same or similar materials. In particular, the core 500 includes a solid glass layer 504 between the layers 502, 512. The layers 502, 512 may be formed in the same or similar manner as the layer 302, and the glass layer 504 may be formed in the same or similar manner as the glass layer 304. The core 500 also includes a mold material 508 adjacent to the glass layer 504 and between the layer 502, 512 as shown. The mold material 508 may be formed in the same or similar manner as the mold material 308. The core 500 further includes vias 506, which may be similar to the vias 306. A core such as the core 500 may be incorporated into a package substrate, e.g., similar to the core layers 102, 202 of FIGS. 1, 2, respectively.

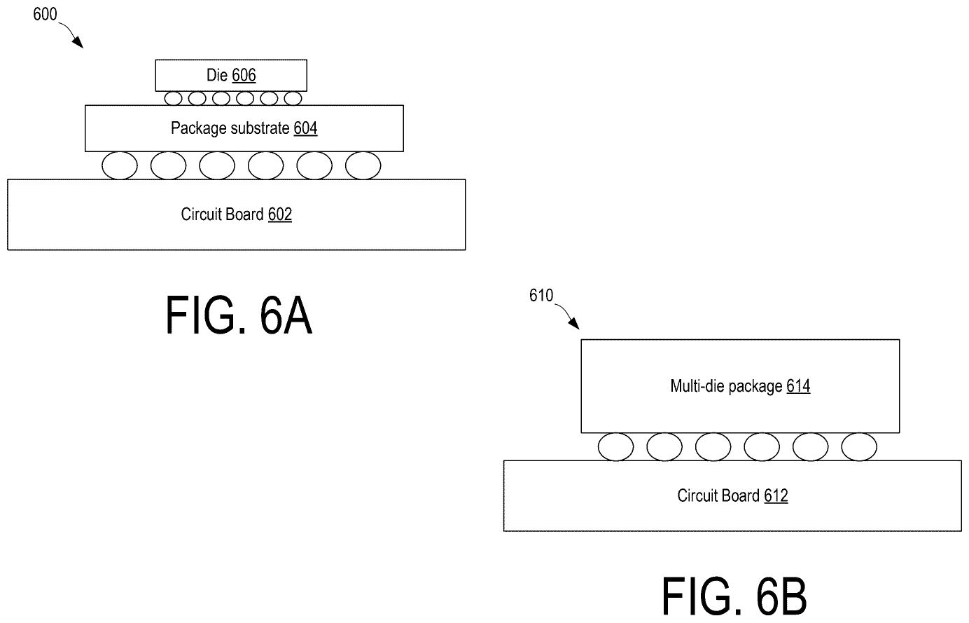

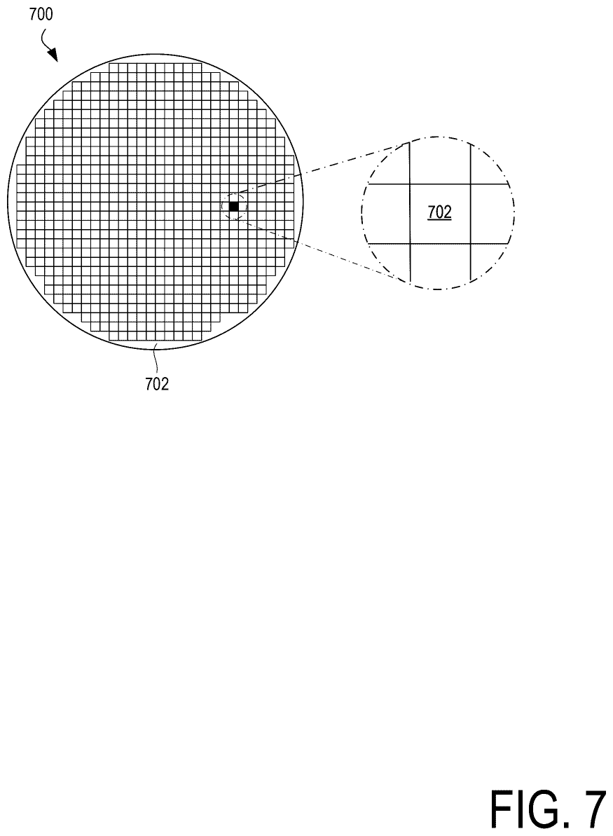

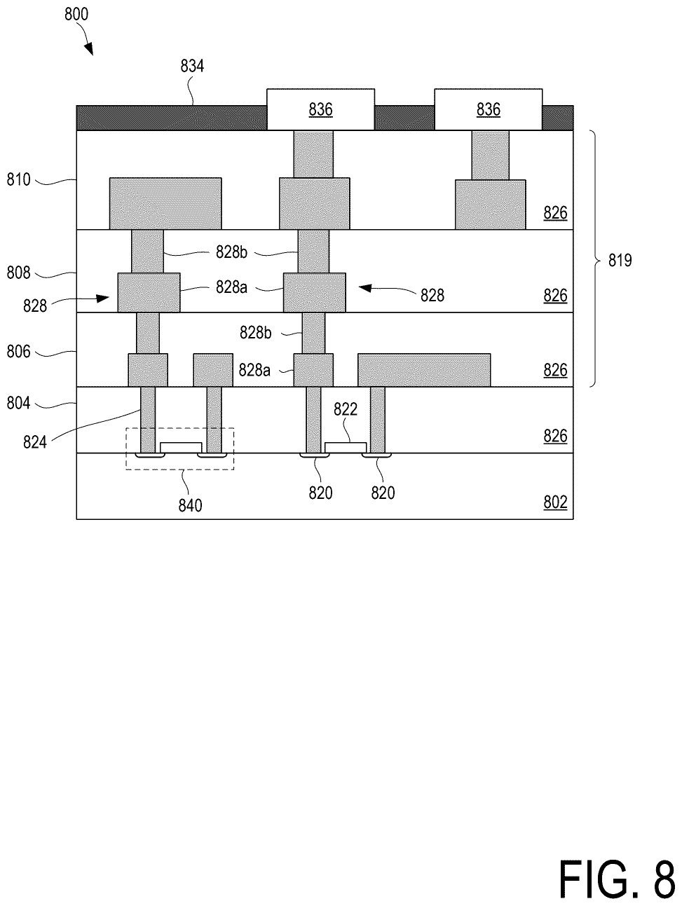

FIGS. 6A-6B illustrate example systems 600, 610 that may incorporate the embodiments described herein. The example system 600 of FIG. 6A includes a circuit board 602, which may be implemented as a motherboard or main board of a computer system in some embodiments. The example system 600 also includes a package substrate 604 with an integrated circuit die 606 attached to the package substrate 604. The die 606 may be a packaged or unpacked integrated circuit product that includes one or more integrated circuit dies (e.g., the die 702 of FIG. 7, the integrated circuit device 800 of FIG. 8) and/or one or more other suitable components. The die 606 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 606 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 606 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 604 may provide electrical connections between the die 606 and the circuit board 602.

Similar to the system 600, the system 610 also includes a circuit board 612, which may be implemented as a motherboard or main board of a computer system in some embodiments. The system 610 also includes a multi-die package 614, which includes multiple integrated circuits/dies (e.g., 606), and interconnections between the dies in one or more metallization layers. The multi-die package 614 may include, for example, one or more silicon interposers, one or more silicon bridges embedded in the package substrate (e.g., an Intel® embedded multi-die interconnect bridge (EMIB)), or combinations thereof.

The main circuit boards 602, 612 may provide electrical connections to other components of a computer system, e.g., memory, storage, network interfaces, peripheral devices, power supplies, etc. The main circuit board may include one or more traces and circuit components to provide interconnects between such computer system components.

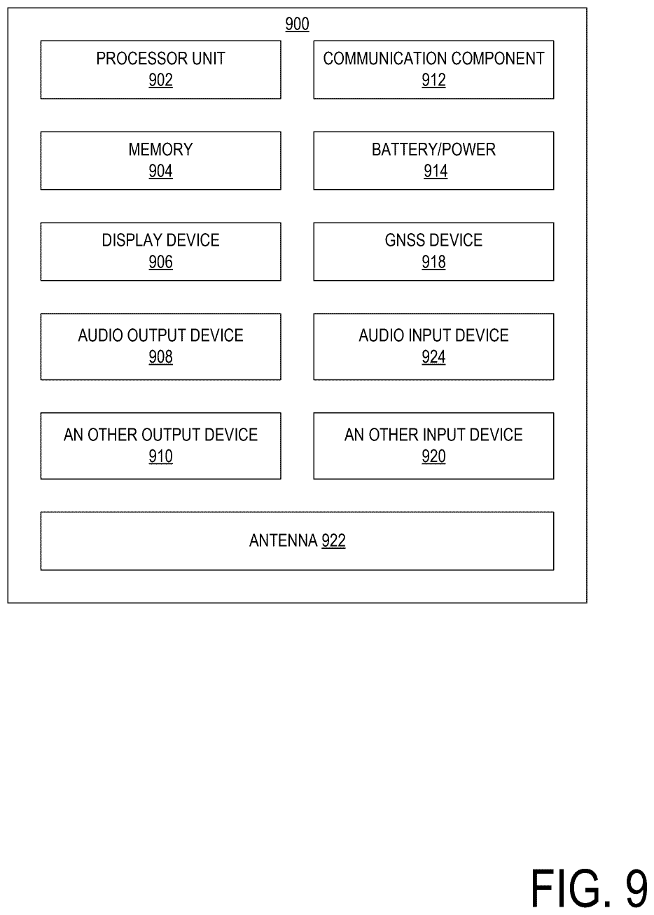

FIG. 7 is a top view of a wafer 700 and dies 702 that may be implemented in or along with any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 902 of FIG. 9) or other logic that is configured to store information in the memory devices or execute instructions stored in the memory array.

FIG. 8 is a cross-sectional side view of an integrated circuit device 800 that may be included in any of the embodiments disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the line 828a of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board or a package substrate, e.g., 112). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die, and the metallization stack 819 can be used to route I/O signals from the conductive contacts 836 to transistors 840 and any other components integrated into the die.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 9 is a block diagram of an example electrical device 900 that may include one or more of the embodiments disclosed herein. For example, any suitable ones of the components of the electrical device 900 may include one or more of integrated circuit devices 800, or integrated circuit dies 702 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a core comprising: a layer comprising glass fibers in an epoxy material; a solid glass layer above the layer comprising glass fibers in the epoxy material; and a dielectric adjacent the solid glass layer; and conductive vias through the core.

Example 2 includes the subject matter of Example 1, wherein the layer comprising glass fibers comprises a sheet of glass fiber weave.

Example 3 includes the subject matter of Example 1 or 2, wherein the epoxy material is an organic material, and the dielectric is an organic material.

Example 4 includes the subject matter of any one of Examples 1-3, wherein the dielectric is above and adjacent to the solid glass layer.

Example 5 includes the subject matter of any one of Examples 1-4, wherein the layer comprising glass fibers in the epoxy material is a first layer comprising glass fibers in the epoxy material, and the apparatus further comprises a second layer comprising glass fibers in an epoxy material above the solid glass layer.

Example 6 includes the subject matter of Example 5, wherein the second layer comprising glass fibers comprises a sheet of glass fiber weave.

Example 7 includes the subject matter of any one of Examples 1-6, wherein the dielectric comprises spherical silica fillers within the dielectric.

Example 8 includes the subject matter of any one of Examples 1-7, wherein the solid glass layer comprises at least 23 percent Silicon and at least 26 percent Oxygen by weight.

Example 9 includes the subject matter of any one of Examples 1-8, wherein the solid glass layer has a rectangular prism volume.

Example 10 includes the subject matter of any one of Examples 1-9, further comprising first buildup layers above the core and second buildup layers below the core, wherein the conductive vias electrically couple metal traces in the first buildup layers and metal traces in the second buildup layers.

Example 11 is a device comprising the apparatus of any one of Examples 1-10 and an integrated circuit die coupled to the apparatus.

Example 12 is an integrated circuit package comprising: a core comprising: a glass fiber prepreg layer; a solid glass layer above the glass fiber prepreg layer; and a dielectric adjacent the solid glass layer; first buildup layers on a first side the core; second buildup layers on a second side of the core opposite the first; and conductive vias through the core, the vias electrically coupling metal traces in the first buildup layers and metal traces in the second buildup layers.

Example 13 includes the subject matter of Example 12, wherein the glass fiber prepreg layer comprises one or more sheets of glass fiber weave.

Example 14 includes the subject matter of Example 12 or 13, wherein the glass fiber prepreg layer and the dielectric each comprise an organic material.

Example 15 includes the subject matter of any one of Examples 12-14, wherein the dielectric is above and adjacent to the solid glass layer.

Example 16 includes the subject matter of any one of Examples 12-15, wherein the glass fiber prepreg layer is a first glass fiber prepreg layer and the core further comprises a second glass fiber prepreg layer above the solid glass layer.

Example 17 is an integrated circuit device comprising the package of any one of Examples 12-16 and an integrated circuit die coupled to the package.

Example 18 is a system comprising a processor and memory, the processor comprising the integrated circuit device of Example 17.

Example 19 is a system comprising: memory; and a processor comprising an integrated circuit die coupled to a package substrate, the package substrate comprising a core and buildup layers on opposite sides of the core, the core comprising: a first layer comprising a glass fiber weave; a second layer above the first layer, the second layer comprising solid glass; a dielectric adjacent the second layer; and vias electrically coupling metal traces within the buildup layers on opposite sides of the core.

Example 20 includes the subject matter of Example 19, wherein the first layer comprises a sheet of glass fiber weave in an epoxy material.

Example 21 includes the subject matter of Example 20, wherein the epoxy material and the dielectric each comprise organic materials.

Example 22 includes the subject matter of any one of Examples 19-21, wherein the dielectric is above and adjacent to the second layer.

Example 23 includes the subject matter of any one of Examples 19-22, wherein the core further comprises a third layer comprising a glass fiber weave, the third layer above the second layer.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying figures. It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). For the purposes of the present disclosure, the phrase “A and at least one of B and C” means (A and B), (A and C), or (A and B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a core comprising:
a layer comprising glass fibers in an epoxy material;
a solid glass layer above the layer comprising glass fibers in the epoxy material; and
a dielectric adjacent the solid glass layer; and
conductive vias through the core.

2. The apparatus of claim 1, wherein the layer comprising glass fibers comprises a sheet of glass fiber weave.

3. The apparatus of claim 1, wherein the epoxy material is an organic material, and the dielectric is an organic material.

4. The apparatus of claim 1, wherein the dielectric is above and adjacent to the solid glass layer.

5. The apparatus of claim 1, wherein the layer comprising glass fibers in the epoxy material is a first layer comprising glass fibers in the epoxy material, and the apparatus further comprises a second layer comprising glass fibers in an epoxy material above the solid glass layer.

6. The apparatus of claim 5, wherein the second layer comprising glass fibers comprises a sheet of glass fiber weave.

7. The apparatus of claim 1, wherein the dielectric comprises spherical silica fillers within the dielectric.

8. The apparatus of claim 1, wherein the solid glass layer comprises at least 23 percent Silicon and at least 26 percent Oxygen by weight.

9. The apparatus of claim 1, wherein the solid glass layer has a rectangular prism volume.

10. The apparatus of claim 1, further comprising first buildup layers above the core and second buildup layers below the core, wherein the conductive vias electrically couple metal traces in the first buildup layers and metal traces in the second buildup layers.

11. An integrated circuit package comprising:
a core comprising:
a glass fiber prepreg layer;
a solid glass layer above the glass fiber prepreg layer; and
a dielectric adjacent the solid glass layer;
first buildup layers on a first side the core;
second buildup layers on a second side of the core opposite the first side; and
conductive vias through the core, the conductive vias electrically coupling metal traces in the first buildup layers and metal traces in the second buildup layers.

12. The integrated circuit package of claim 11, wherein the glass fiber prepreg layer comprises one or more sheets of glass fiber weave.

13. The integrated circuit package of claim 11, wherein the glass fiber prepreg layer and the dielectric each comprise an organic material.

14. The integrated circuit package of claim 11, wherein the dielectric is above and adjacent to the solid glass layer.

15. The integrated circuit package of claim 11, wherein the glass fiber prepreg layer is a first glass fiber prepreg layer and the core further comprises a second glass fiber prepreg layer above the solid glass layer.

16. The integrated circuit package of claim 11, further comprising an integrated circuit die coupled to metal traces in at least one of the first buildup layers and the second buildup layers.

17. A system comprising:
memory; and
a processor comprising an integrated circuit die coupled to a package substrate, the package substrate comprising a core and buildup layers on opposite sides of the core, the core comprising:
a first layer comprising a glass fiber weave;
a second layer above the first layer, the second layer comprising solid glass;
a dielectric adjacent the second layer; and
vias electrically coupling metal traces within the buildup layers on opposite sides of the core.

18. The system of claim 17, wherein the first layer comprises a sheet of glass fiber weave in an epoxy material.

19. The system of claim 17, wherein the dielectric is above and adjacent to the second layer.

20. The system of claim 17, wherein the core further comprises a third layer comprising a glass fiber weave, the third layer above the second layer.
